(19) United States
(12) Patent Application Publication
(10) Pub. No.: US 2025/0384948 A1
(43) Pub. Date: Dec. 18, 2025

(54) VOLTAGE THRESHOLD DISTRIBUTION USING READ ESTIMATE

(71) Applicant: Micron Technology, Inc., Boise, ID (US)

(72) Inventors: Zhaohang Yu, Shanghai (CN); Zihao Gong, Shanghai (CN); Min Rui Ma, Shanghai (CN)

(21) Appl. No.: 19/221,289

(22) Filed: May 28, 2025

Related U.S. Application Data
(60) Provisional application No. 63/659,444, filed on Jun. 13, 2024.

(51) Int. Cl. G11C 29/50; G11C 7/22

(52) U.S. Cl. CPC G11C 29/50004; G11C 7/22; G11C 2029/5004

(57) ABSTRACT

Methods, systems, and devices for voltage threshold distribution using read estimate are described. A memory system may determine a voltage threshold distribution of memory cells. For a target memory cell, the memory system may identify the type of memory cell and identify voltage ranges associated with the memory cell based on the type. The memory system may set reference voltages for each voltage range, and read the memory cell using the reference voltages by counting the quantity of logic states between the reference voltages and endpoints of the voltage ranges. The memory system may increment the reference voltages and reread the memory cell using the incremented reference voltages. After incrementing the reference, the memory system may use the counts determined during the reading operations to determine the voltage threshold distribution.

### CROSS REFERENCE

The present Application for Patent claims priority to U.S. Patent Application No. 63/659,444 by Yu et al., entitled “VOLTAGE THRESHOLD DISTRIBUTION USING READ ESTIMATE,” filed Jun. 13, 2024, which is assigned to the assignee hereof, and which is expressly incorporated by reference in its entirety herein.

### TECHNICAL FIELD

The following relates to one or more systems for memory, including voltage threshold distribution using read estimate.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports voltage threshold distribution using read estimate in accordance with examples as disclosed herein.

FIG. 2 shows an example of a process that supports voltage threshold distribution using read estimate in accordance with examples as disclosed herein.

FIG. 3 shows an example of a read voltage diagram that supports voltage threshold distribution using read estimate in accordance with examples as disclosed herein.

FIG. 4 shows a block diagram of a memory system that supports voltage threshold distribution using read estimate in accordance with examples as disclosed herein.

FIG. 5 shows a flowchart illustrating a method or methods that support voltage threshold distribution using read estimate in accordance with examples as disclosed herein.

### DETAILED DESCRIPTION

Some memory systems (e.g., NAND systems) may include memory cells that may be activated (e.g., accessed) based on a voltage threshold of a respective memory cell being satisfied. In some cases, memory cells of a memory system may have different voltage thresholds. In some such cases, when errors occur, the memory system may analyze the distribution of voltage thresholds across the memory cells to determine the cause of such errors. In some examples, to identify the distribution of the voltage thresholds, the memory system may read the memory cells a quantity of times, using different read trims, and may determine a count of logic states (e.g., 1s and 0s) relative to various voltage thresholds for the. That is, the memory system may update the read trim (e.g., the voltage used to read the memory cells) for each read, and may determine the count of logic states during each read to determine the distribution of voltage thresholds for the associated memory cells. However, adjusting the read trim for each read operation may be associated with relatively high latency. Likewise, determining the distribution of voltage thresholds in such a manner may reduce available processing bandwidth of the memory system. Accordingly, a low latency method for determining the voltage threshold distribution by the memory system may be desirable.

A low latency method for determining a voltage threshold distribution by a memory system is described herein. In accordance with examples as described herein, the memory system may be configured to perform a coarse threshold estimate (CTE) read to determine the voltage threshold distribution of memory cells with a relatively low latency. For a target memory cell, the memory system may identify the type of memory cell (e.g., as a single-level cell (SLC), a multi-level cell (MLC), a triple-level cell (TLC), a quad-level cell (QLC)) and identify voltage ranges associated with the memory cell based on the identified type of memory cell. For example, the memory system may divide a total voltage range associated with the memory cell into a quantity of voltage ranges corresponding to the type of memory cell.

The memory system may perform a CTE read to determine the voltage distribution of memory cells by setting reference voltages for each voltage range, and reading the memory cell using the reference voltages (e.g., by counting the quantity of logic states between the reference voltages and endpoints of the respective voltage ranges). Then, the memory system may increment the reference voltages and reread the memory cell using the incremented reference voltages. After incrementing the reference voltages until the reference voltages are at or near the endpoints of the respective voltage ranges, the memory system may count the various logic states determined during the reading operations to determine the voltage threshold distribution. That is, the memory system may increment the reference voltages after each read operation (e.g., based on determining the reference voltages do not satisfy the endpoints of the respective voltage ranges), such that after incrementing the reference voltages a quantity of times, the reference voltages may satisfy the endpoints. Determining the voltage threshold distribution in such a manner may reduce latency otherwise incurred by incrementing trim settings of the memory system. Additionally, performing the read operations for each voltage range may enable the memory cell to be read concurrently for each voltage range, which may reduce latency associated with determining the voltage threshold distribution. Further, determining the voltage threshold distribution in such a manner may improve the system's overall performance and ability to execute commands (e.g., host commands) efficiently.

In addition to applicability in memory systems as described herein, techniques for voltage threshold distribution using read estimate may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by determining a voltage distribution of a memory system using a CTE read, which may decrease processing or latency times, improve response times, or otherwise improve user experience, among other benefits.

Features of the disclosure are illustrated and described in the context of systems, devices, and circuits. Features of the disclosure are further illustrated and described in the context of processes, read diagrams, and flowcharts.

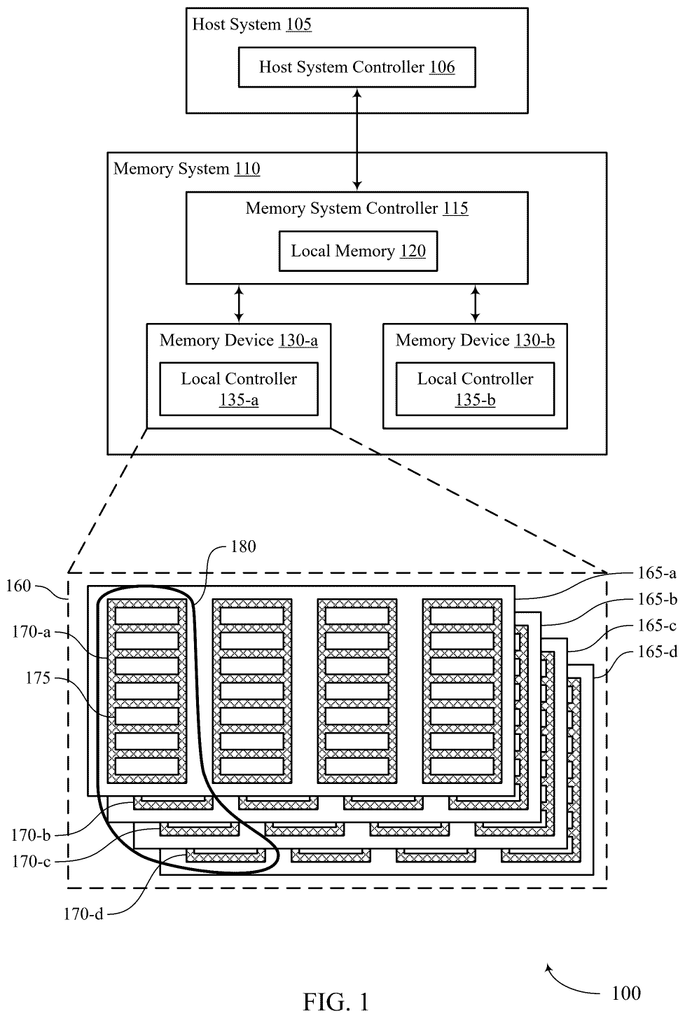

FIG. 1 shows an example of a system 100 that supports voltage threshold distribution using read estimate in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as SLCs. Additionally, or alternatively, a NAND memory device 130 may include memory cells configured to each store multiple bits of information, which may be referred to as MLCs if configured to each store two bits of information, as TLCs if configured to each store three bits of information, as QLCs if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

A low latency method for determining a voltage threshold distribution by the memory system 110 is described herein. In accordance with examples as described herein, the memory system 110 may be configured to perform a CTE read to determine the voltage threshold distribution of memory cells with a relatively low latency. For a target memory cell, the memory system 110 may identify the type of memory cell (e.g., as a single-level cell (SLC), a multi-level cell (MLC), a triple-level cell (TLC), a quad-level cell (QLC)) and identify voltage ranges associated with the memory cell based on the identified type of memory cell. For example, the memory system 110 may divide a total voltage range associated with the memory cell into a quantity of voltage ranges corresponding to the type of memory cell.

The memory system 110 may perform a CTE read to determine the voltage distribution of memory cells by setting reference voltages for each voltage range, and reading the memory cell using the reference voltages (e.g., by counting the quantity of logic states between the reference voltages and endpoints of the respective voltage ranges). Then, the memory system 110 may increment the reference voltages and reread the memory cell using the incremented reference voltages. After incrementing the reference voltages until the reference voltages are at or near the endpoints of the respective voltage ranges, the memory system 110 may count the various logic states determined during the reading operations to determine the voltage threshold distribution. That is, the memory system 110 may increment the reference voltages after each read operation (e.g., based on determining the reference voltages do not satisfy the endpoints of the respective voltage ranges), such that after incrementing the reference voltages a quantity of times, the reference voltages may satisfy the endpoints. Determining the voltage threshold distribution in such a manner may reduce latency otherwise incurred by incrementing trim settings of the memory system 110. Additionally, performing the read operations for each voltage range may enable the memory cell to be read concurrently for each voltage range, which may reduce latency associated with determining the voltage threshold distribution. Further, determining the voltage threshold distribution in such a manner may improve the overall performance of the system 100 and an ability to execute commands (e.g., host commands) efficiently at the memory system 110, among other advantages.

The system 100 may include any quantity of non-transitory computer readable media that support voltage threshold distribution using read estimate. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

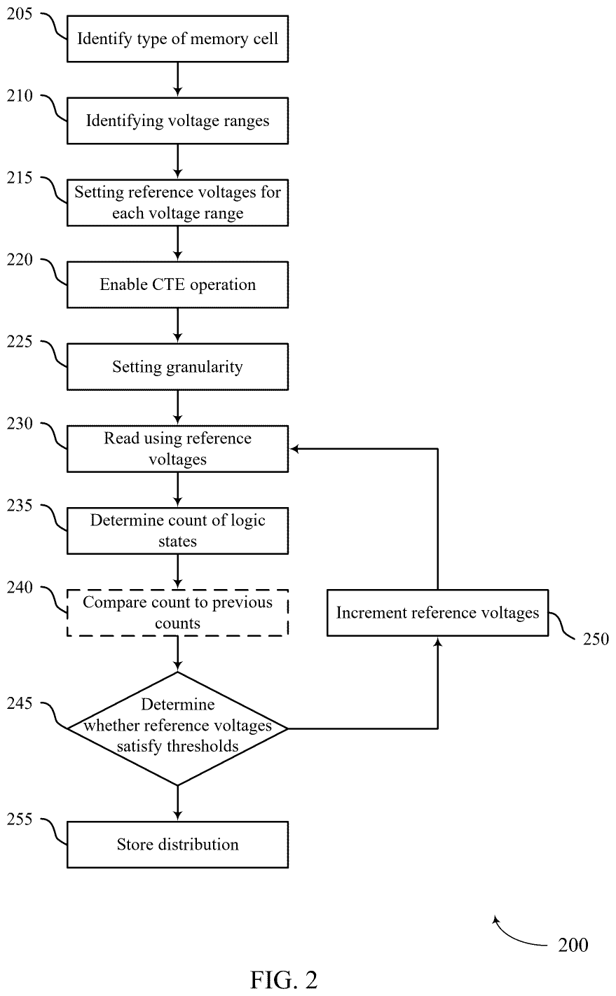

FIG. 2 shows an example of a process 200 that supports determining a voltage threshold distribution using read estimate in accordance with examples as disclosed herein. The process 200 may implement aspects or operations of a system, which may be an example of a system 100, as described with reference to FIG. 1. For example, the process 200 may be implemented by a memory system, which may be an example of a memory system 110. The process 200 may illustrate operations performed by the memory system to determine a voltage threshold distribution of the memory system. That is, the memory system may perform the operations of the process 200 to determine a voltage distribution of memory cells implemented by the memory system.

Aspects of the process 200 may be implemented by one or more controllers, among other components. Additionally, or alternatively, aspects of the process 200 may be implemented as instructions stored in one or more memories (e.g., firmware stored in one or more memories coupled with a memory system controller 115, as described with reference to FIG. 1). For example, the instructions, when executed by one or more controllers (e.g., the memory system controller 115), may cause the one or more controllers (or a device or a system) to perform the operations of the process 200.

The memory system may include one or more memory devices (e.g., NAND devices), and one or more memory system controllers (e.g., NAND controllers), which may be examples of memory devices 130 and the memory system controller 115 as described with reference to FIG. 1. In some examples, the one or more memory devices may each include one or more memory arrays (e.g., NAND arrays) and one or more local controllers, which may be examples of local controllers 135. In some examples, the one or more memory system controllers, or the one or more local controllers, may be configured to perform (e.g., facilitate) the operations of the process 200 for the memory system. The one or more memory arrays may each include a quantity of memory cells (e.g., NAND cells), each configured to store one or more bits of information for the memory system. In some examples, the memory cells may be accessed based on applying a voltage to the memory cells. For example, a memory cell may be written with a logic state based on applying a voltage that satisfies a threshold value to the memory cell. Likewise, a memory cell may be read based on applying a voltage to the memory cell and comparing the voltage to the threshold voltage to determine its logic state.

In some cases, a memory system may include different types of memory cells. That is, the memory cells may each be configured to store a respective quantity of bits. For example, the memory cells may be configured as SLCs, each operable to store a single bit of information. In other examples, the memory cells may be configured as MLCs, each operable to store two bits of information. Further, the memory cells may be configured as TLCs, each operable to store three bits of information. In some cases, the memory cells may be configured to store more than three bits of information based on configuring the memory cells as QLCs, or other multiple-level cells. The process 200 described herein is associated with determining the voltage distribution of a target memory cell, which may be used to determine the voltage distribution of the memory cells associated with the one or more memory arrays. That is, the process 200 may be performed for a quantity of memory cells, at least partially concurrent in time.

At 205, the type of memory cell may be identified. That is, the memory system controller may identify the type of the target memory cell. For example, the memory system may determine whether the memory cell is an SLC, an MLC, a TLC, a QLC, or another multiple-level cell. In some examples, at 205, the memory system may determine the type of each memory cell associated with the one or more memory arrays.

At 210, voltage ranges associated with the memory cell may be identified. For example, the memory system controller may identify the voltage ranges associated with the memory cell based on identifying the type of the memory cell. That is, the memory cell may be associated with a voltage range over which the memory cell may be read, and the memory system may divide the voltage range into a quantity of voltage ranges (e.g., voltage subranges, parts of the voltage range).

In some cases, the quantity of voltage ranges may correspond to the type of memory cell, such that the memory system may divide the voltage range based on the type of the memory cell. For example, the memory system may identify the memory cell is an SLC, and the memory system may not divide the voltage range into additional voltage ranges (e.g., SLCs may be associated with a single voltage range). In another example, the memory system may identify the memory cell is an MLC, and the memory system may divide the voltage range into two voltage ranges. Further, the memory system may identify the memory cell is a TLC, and the memory system may divide the voltage range into three voltage ranges. In some cases, at 210, the memory system may identify the voltage ranges associated with each memory cell of the one or more memory arrays.

At 215, reference voltages associated with each voltage range may be set. For example, the memory system controller may set a reference voltage for each voltage range associated with the memory cell. In some cases, the memory system may set each reference voltage at or near a median voltage of each voltage range. In some cases, the memory system may set each reference voltage based on identifying a start point (e.g., a starting voltage) and an endpoint (e.g., an ending voltage) of each voltage range. For example, setting the reference voltage at the median voltage may be based on identifying a voltage value between (e.g., equidistant between, in the approximate middle of) the start point and the endpoint of the respective voltage range.

In examples where the memory cell is an SLC, the memory system may set a single reference voltage for the voltage range associated with the memory cell. In examples where the memory cell is an MLC, the memory system may set two reference voltages for the two voltage ranges associated with the memory cell. In examples, where the memory cell is a TLC, the memory system may set three reference voltages for the three voltage ranges associated with the memory cell. In some implementations, the reference voltages may be or may be associated with read trims, such that reading the memory cell may be based on the respective read trim. For example, the memory cell may be read relative to the reference voltages, such that a voltage read from the memory cell may be compared to the reference voltage. In some cases, at 215, the memory system controller may set the reference voltages associated with each memory cell of the one or more memory arrays.

At 220, a CTE read operation may be enabled. In some cases, the memory system controller may enable the CTE read operation. For example, the memory system may enable the CTE read operation based on identifying one or more conditions of the memory system, or based on information stored at the memory system (e.g., a mode register). In other cases, the host system may enable the CTE read operation based on transmitting an indication (e.g., a command) associated with enabling the CTE read operation.

As described herein, a CTE read operation may include a quantity of read operations associated with reading memory cells of the memory system and determining a voltage distribution by the memory system based on reading the memory cells. That is, the memory system may be configured to perform a quantity of read operations and increment the reference voltages after each read operation (e.g., based on determining the reference voltages do not satisfy thresholds of the respective voltage ranges), such that after incrementing the reference voltages a quantity of times, the reference voltages may satisfy thresholds (e.g., endpoints) associated with the respective voltage ranges. In some cases, performing the CTE read operation may include refraining from transferring information associated with determining the voltage distribution from a memory device of the memory system to the memory system controller (e.g., or a direct memory access controller, a decoder, firmware) or to a host system coupled with the memory system. In some cases, the CTE read operation may be enabled for the target memory cell. In other cases, the CTE read operation may be enabled for each memory cell of the one or more memory arrays.

At 225, a granularity of the read operation may be set. That is, the memory system controller may determine a granularity associated with performing the read operation, and may set the granularity according to the determination. In some cases, the memory system controller may determine to perform the read operation such that 8 bits of information are read for each byte of information. In some such cases, the memory system controller may set the granularity to indicate that 8 bits of information are read for each byte of information. In some examples, setting the granularity may include setting an option associated with the CTE read operation. That is, when the CTE read operation is enabled, the granularity may be set based on an indication associated with the CTE read operation. In some cases, the granularity of the read operation may be set for the target memory cell. In other cases, the granularity of the read operation may be set for each memory cell of the one or more memory arrays.

At 230, the memory cell may be read using the reference voltages. That is, the memory system controller may read the memory cell based on the reference voltages associated with each voltage range of the memory cell. In some cases, reading the memory cell may include determining (e.g., reading) logic states within each voltage range using the respective reference voltage. The logic states may be determined by counting a quantity of logic states within a respective subrange of each voltage range.

For example, reading the memory cell may include counting a quantity of logic states between the reference voltages and the endpoints of the respective voltage ranges. In some cases, reading the memory cell may include applying a read voltage the same as or similar to the reference voltage in each voltage range and determining a count of the first logic state between the reference voltage and the endpoint of the voltage range. For example, applying a read voltage within the reference voltage and the endpoint of the voltage may enable determining a count of the first logic state. In some implementations, the memory cell may be read according to the granularity set at operation 225 of the process 200. In some cases, reading the memory cell may including reading each memory cell of the one or more memory arrays.

At 235, the count of logic states may be determined. That is, the memory system controller may determine a quantity of first logic states and a quantity of second logic states based on reading the memory cell. For example, the memory system controller may count a quantity of first logic states between the reference voltage and the endpoints of the respective voltage ranges. In some examples, the memory system controller may count a quantity of second logic states between the reference voltage and the start points of the respective voltage ranges.

In other examples, the quantity of the second logic states may be determined based on determining the quantity of the first logic states and comparing the quantity of the first logic states to a total quantity of logic states. In examples, where the memory cell is an SLC, reading the memory cell may include counting a quantity of the first logic states between the reference voltage and the endpoint of the voltage range. In examples where the memory cell is an MLC, reading the memory cell may include counting a quantity of the first logic states between the reference voltage and the endpoint of a first voltage range, and counting a quantity of the first logic states between the reference voltage and the endpoint of a second voltage range (e.g., based on the MLC being associated with two voltage ranges).

In examples, where the memory cell is a TLC, reading the memory cell may include counting a quantity of the first logic states between the reference voltage and the endpoint of a first voltage range, counting a quantity of the first logic states between the reference voltage and the endpoint of a second voltage range, and counting a quantity of the first logic states between the reference voltage and the endpoint of a third voltage range (e.g., based on the TLC being associated with three voltage ranges). In some cases, each voltage range of the memory cell may be read concurrently (e.g., during a same duration).

In some cases, determining the count of logic states may include recording (e.g., storing) the count of logic states. For example, the quantity of the first logic states and the quantity of the second logic states may be recorded. In some cases, determining the count of logic states for the memory cell may include determining the count of logic states for each memory cell of the one or more memory arrays. In some examples, storing the counts of logic states may include storing a value of the counts of the first logic states or the second logic states in the memory cells of the one or more memory arrays.

At 240, the count of logic states may be compared to previous counts of logic states. In a first cycle through the process 200, the count of logic states may not be compared to previous counts of logic states because there are not previous counts of logic states stored to the memory system. In subsequent cycles through the process 200, the count of logic states may be compared to previous counts of logic states determined based on prior read operations. In some cases, comparing the count to previous counts may include determining a quantity of the first logic states and a quantity of the second logic states associated with a most-recent read operation, and identifying a quantity of the first logic states and a quantity of the second logic states associated with one or more previous read operations.

For example, the quantity of the first logic states associated with the most-recent read operation may be compared with the quantity of the first logic states associated with the one or more previous read operations. Likewise, the quantity of the second logic states associated with the most-recent read operation may be compared with the quantity of the second logic states associated with the one or more previous read operations. In some cases, the quantity of the logic states associated with the most-recent read operation may be different than the quantity of the logic states associated with the one or more previous read operations. In some such cases, the differences may be stored in the memory cells of the one or more memory arrays. In some cases, the count of logic states may be compared on a cell-by-cell basis, such that the count of logic states at the target memory cell may be compared to the previous count of logic states associated with the target memory cell. In some cases, the count of logic states may be compared on an array-by-array basis (e.g., a device-by-device basis, a system-by-system basis), such that the counts of logic states at each memory cell of the one or more memory arrays may be compared to the previous counts of logic states associated with the respective memory cells of the one or more memory arrays.

At 245, it may be determined whether the reference voltages satisfy respective thresholds. That is, the memory system controller may determine whether the reference voltages satisfy respective thresholds associated with the voltage ranges. In some cases, the thresholds may be associated with endpoints of the voltage ranges, where the endpoints are voltages at upper limits of the respective voltage ranges. The memory system controller may determine, for each voltage range, whether the reference voltage associated with the respective voltage range has satisfied (e.g., met, reached) the threshold associated with the respective voltage range. For example, the memory system may increment the reference voltages after each read operation, such that after incrementing the reference voltages a quantity of times, the reference voltages may satisfy the thresholds.

In examples where the memory cell is an SLC, the memory system controller may determine whether the reference voltage has reached an endpoint of the voltage range. In examples where the memory cell is an MLC, the memory system controller may determine whether the reference voltage associated with the first voltage range has reached an endpoint of the first voltage range, and whether the reference voltage associated with the second voltage range has reached an endpoint of the second voltage range. In examples where the memory cell is a TLC, the memory system controller may determine whether the reference voltage associated with the first voltage range has reached an endpoint of the first voltage range, whether the reference voltage associated with the second voltage range has reached an endpoint of the second voltage range, and whether the reference voltage associated with the third voltage range has reached an endpoint of the third voltage range.

In some cases, the memory system may controller determine that the reference voltages satisfy the thresholds, and the process 200 may continue to operation 255. In other cases, the memory system controller may determine that the reference voltages do not satisfy the thresholds, and the process 200 may continue to operation 250. In some cases, the determination may be performed for each memory cell of the one or more memory arrays. That is, the memory system controller may determine, for each memory cell, whether the reference voltages satisfy the thresholds. In some cases, the memory cells may be incremented at different rates, such that a quantity of the memory cells may be associated with reference voltages that satisfy the thresholds, and a quantity of memory cells associated with reference voltages that do not satisfy the thresholds.

At 250, the reference voltages may be incremented. That is, the memory system controller may increment the reference voltages associated with each voltage range based on determining the reference voltages do not satisfy the thresholds associated with the voltage ranges. Incrementing the reference voltages may include increasing the references voltages by an incremental unit (e.g., an incremental voltage). For example, the reference voltages may be increased by a set or predetermined voltage value. In some examples, incrementing the reference voltages may set the reference voltages to the incremented values. In some cases, incrementing the reference voltages may including incrementing the reference voltages associated with each memory cell of the one or more memory arrays.

After incrementing the reference voltages, the process 200 may continue to operation 230. For example, after incrementing the reference voltages, the memory cell may be read again using the incremented reference voltages. That is, the reference voltages may be incremented a quantity of times, and the memory cell may be reread using the incremented reference voltages the quantity of times until the reference voltages satisfy the thresholds.

At 255, the voltage threshold distribution may be stored. The memory system controller may identify the voltage threshold distribution based on reading the target memory cell using each of the incremented reference voltages and determining the count of the logic states for each time the target memory cell is read. In some cases, the memory system controller may determine the voltage threshold distribution by identifying the reference voltage associated with an even distribution of the first logic state and the second logic state (e.g., a same or nearly same quantity of the first logic state and the second logic state). For example, the memory system may determine the reference voltage for each voltage range associated with producing an even distribution of the first logic state and the second logic state based on the reference voltage.

In some such examples, the memory system may identify the voltage threshold distribution by performing such a determination for each memory cell of the one or more memory arrays. After determining the reference voltages associated with producing even distributions, the reference voltages may be indicative of the voltage thresholds of each memory cell. The memory system may identify the voltage threshold distribution across the one or more memory arrays by aggregating the voltage thresholds of each memory cell of the one or more memory arrays. The memory system controller may store an indication of the voltage threshold distribution in the one or more memory arrays, or another memory (e.g., a register, a log, a table) of the memory system.

Implementing the process 200 may enable the memory system to determine the voltage threshold distribution with relatively low latency. Determining the voltage threshold distribution by performing the CTE read may reduce latency otherwise incurred by incrementing trim settings of the memory system during each read operation. Additionally, performing the read operations for each voltage range may enable the memory cell to be read concurrently for each voltage range, which may reduce latency associated with determining the voltage threshold distribution. Further, determining the voltage threshold distribution in such a manner may improve the overall performance of the system and an ability to execute commands (e.g., host commands) efficiently at the memory system, among other advantages.

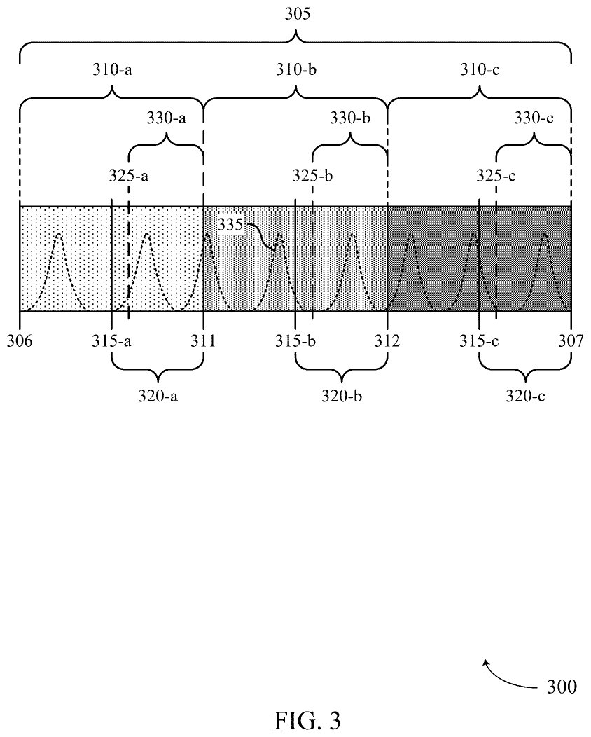

FIG. 3 shows an example of a read voltage diagram 300 that supports voltage threshold distribution using read estimate in accordance with examples as disclosed herein. The read diagram 300 may illustrate aspects or operations of a system, which may be an example of a system 100, as described with reference to FIG. 1. For example, the read diagram 300 may illustrate reading a memory cell of a memory system, which may be an example of a memory system 110. The read diagram 300 may illustrate processes associated with operations of a process 200, as described with reference to FIG. 2. For example, the read diagram 300 may illustrate reading the memory cell using reference voltages, as described in operation 230 of the process 200.

The read diagram 300 may illustrate a total voltage range 305 of a memory cell. The total voltage range 305 may be associated with voltage which may be applied to the memory cell to access (e.g., read) the memory cell. In some cases, the total voltage range 305 may be characterized by a voltage limit 306 and a voltage limit 307 of the total voltage range, each of which form upper and lower bounds of the total voltage range 305. In some examples, the voltage limit 306 may be a lower limit of the total voltage range 305 and may be at or near 0V, and the voltage limit 307 may be an upper limit of the total voltage range 305 and may be at or near to 10V, for example.

The read diagram 300 may illustrate one or more voltage ranges 310 of the memory cell. The voltage ranges 310 may be portions of the total voltage range 305, such that dividing the total voltage range 305 may result in the voltage ranges 310. The read diagram 300 may illustrate the total voltage range 305 being divided into three voltage ranges 310 based on the memory cell being a TLC. That is, the total voltage range 305 may be partitioned into three voltage ranges 310 because the type of the memory cell is a TLC. For example, the memory cell may be associated with a voltage range 310-a, a voltage range 310-b, and a voltage range 310-c. However, in other examples, a memory cell may be of a different type and may include a different quantity of voltage ranges 310.

The voltage ranges 310 may each be characterized by lower limits (e.g., lower bounds) and upper limits (e.g., upper bounds) of the respective voltage ranges 310. For the voltage range 310-a, the voltage limit 306 may be a lower limit (e.g., a lower bound) of the voltage range 310-a, and a voltage limit 311 may be an upper limit (e.g., an upper bound) of the voltage range 310-a. For the voltage range 310-b, the voltage limit 311 may be a lower limit (e.g., a lower bound) of the voltage range 310-b, and a voltage limit 312 may be an upper limit (e.g., an upper bound) of the voltage range 310-b. For the voltage range 310-c, the voltage limit 312 may be a lower limit (e.g., a lower bound) of the voltage range 310-c, and a voltage limit 307 may be an upper limit (e.g., an upper bound) of the voltage range 310-c. In some examples, the voltage limit 311 may be at or near 3.33V and the voltage limit 312 may be at or near to 6.67V, for example.

The read diagram 300 may illustrate reference voltages 315 of the memory cell. The reference voltages 315 may be read trims associated with reading the memory cell. Each reference voltage 315 may be associated with reading the memory cell within the respective voltage range 310. That is, each voltage range 310 may include a respective reference voltage 315. For example, the voltage range 310-a may include a reference voltage 315-a, the voltage range 310-b may include a reference voltage 315-b, and the voltage range 310-c may include a reference voltage 315-c.

In some cases, the reference voltages 315 may be associated with median (e.g., middle) voltages of the respective voltage ranges 310, such that the reference voltage 315-a is a median voltage of the voltage range 310-a, the reference voltage 315-b is a median voltage of the voltage range 310-b, and the reference voltage 315-c is a median voltage of the voltage range 310-c. In some examples, the reference voltages 315 may be set as the median voltages within the respective voltage ranges 310 based on the read diagram 300 illustrating a first cycle of the process 200. In some examples, the reference voltage 315-a may be at or near to 2.5V, the reference voltage 315-b may be at or near to 5V, and the reference voltage 315-c may be at or near to 7.5V, for example.

The memory cell may be read using the reference voltages 315 and the voltage ranges 310. For example, the memory cell may be read using each of the reference voltages 315 within the respective voltage ranges 310. In some cases, the memory cell may be read by determining quantities of a logic state within subranges 320 of the voltage ranges 310. The subranges 320 may be defined by the reference voltages 315 and the upper limits (e.g., the upper bounds) of the voltage ranges 310. For example, a subrange 320-a associated with the voltage range 310-a may be defined by the reference voltage 315-a and the voltage limit 311. Likewise, a subrange 320-b associated with the voltage range 310-b may be defined by the reference voltage 315-b and the voltage limit 312. Further, a subrange 320-c associated with the voltage range 310-c may be defined by the reference voltage 315-c and the voltage limit 307.

The memory cell may be read by determining the quantity of first logic states within the subrange 320-a using the reference voltage 315-a to read the memory cell within the voltage range 310-a. Likewise, the memory cell may be read by determining the quantity of the first logic states within the subrange 320-b using the reference voltage 315-b to read the memory cell within the voltage range 310-b. Further, the memory cell may be read by determining the quantity of first logic states within the subrange 320-c using the reference voltage 315-c to read the memory cell within the voltage range 310-c. The read diagram 300 may illustrate voltage distributions 335 associated with the memory cell. In some cases, the voltage distributions 335 may be associated with the distribution of logic states within the total voltage range 305 based on reading the memory cell using the reference voltages 315.

In some cases, after reading the memory cell using the reference voltages 315, the reference voltages 315 may be incremented. That is, the reference voltages 315 may be increased within the respective voltage ranges 310. In some such cases, incrementing the reference voltages 315 may set the reference voltages 315 at new voltage levels, where the new voltage levels will be the new reference voltages 325. For example, the reference voltage 315-a may be incremented to be reference voltage 325-a, the reference voltage 315-b may be incremented to be reference voltage 325-b, and the reference voltage 315-c may be incremented to be reference voltage 325-c.

After incrementing the reference voltages 315 to the reference voltages 325, the memory cell may be read using the reference voltages 325. In some cases, the memory cell may be read by determining quantities of a logic state within subranges 330 of the voltage ranges 310. The subranges 330 may be defined by the reference voltages 325 and the upper limits of the voltage ranges 310. For example, a subrange 330-a associated with the voltage range 310-a may be defined by the reference voltage 325-a and the voltage limit 311. Likewise, a subrange 330-b associated with the voltage range 310-b may be defined by the reference voltage 325-b and the voltage limit 312. Further, a subrange 330-c associated with the voltage range 310-c may be defined by the reference voltage 325-c and the voltage limit 307.

The memory cell may be read by determining the quantity of a first logic state within the subrange 330-a using the reference voltage 325-a to read the memory cell within the voltage range 310-a. Likewise, the memory cell may be read by determining the quantity of the first logic state within the subrange 330-b using the reference voltage 325-b to read the memory cell within the voltage range 310-b. Further, the memory cell may be read by determining the quantity of a first logic state within the subrange 330-c using the reference voltage 325-c to read the memory cell within the voltage range 310-c.

Reading the memory cell using the reference voltages 315 (e.g., or the reference voltages 325) may enable the memory cell to be read concurrently. Reading the memory cell concurrently may reduce latency, which may reduce latency associated with determining the voltage threshold distribution of a memory system, among other benefits.

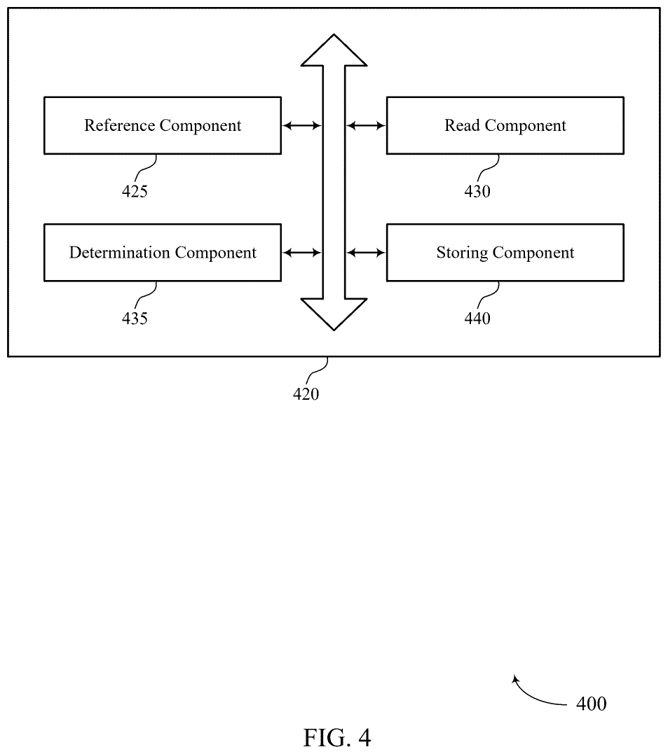

FIG. 4 shows a block diagram 400 of a memory system 420 that supports voltage threshold distribution using read estimate in accordance with examples as disclosed herein. The memory system 420 may be an example of aspects of a memory system as described with reference to FIGS. 1 through 3. The memory system 420, or various components thereof, may be an example of means for performing various aspects of voltage threshold distribution using read estimate as described herein. For example, the memory system 420 may include a reference component 425, a read component 430, a determination component 435, a storing component 440, or any combination thereof. Each of these components, or components of subcomponents thereof (e.g., one or more processors, one or more memories), may communicate, directly or indirectly, with one another (e.g., via one or more buses).

The reference component 425 may be configured as or otherwise support a means for setting a plurality of reference voltages for a plurality of voltage ranges associated with voltage thresholds of memory cells. The read component 430 may be configured as or otherwise support a means for reading, at a first time, the memory cells to identify a count of logic states within each respective voltage range in response to setting the plurality of reference voltages. The determination component 435 may be configured as or otherwise support a means for determining whether the plurality of reference voltages satisfy a threshold value associated with a respective voltage range. In some examples, the reference component 425 may be configured as or otherwise support a means for increasing the plurality of reference voltages in response to determining that the plurality of reference voltages fail to satisfy the threshold value associated with the respective voltage range. In some examples, the read component 430 may be configured as or otherwise support a means for reading, at a second time, the memory cells to identify a second count of logic states within each respective voltage range in response to increasing the plurality of reference voltages. The storing component 440 may be configured as or otherwise support a means for storing a distribution of the voltage thresholds of the memory cells in accordance with the second count of logic states within each respective voltage range and the plurality of reference voltages satisfying the threshold value associated with the respective voltage range.

In some examples, the determination component 435 may be configured as or otherwise support a means for determining that the plurality of increased reference voltages satisfy the threshold value associated with the respective voltage range, where storing the distribution of the voltage thresholds of the memory cells is in response to determining that the plurality of increased reference voltages satisfy the threshold value associated with the respective voltage range.

In some examples, to support increasing the plurality of reference voltages, the reference component 425 may be configured as or otherwise support a means for increasing a voltage of each reference voltage within the respective voltage range.

In some examples, the read component 430 may be configured as or otherwise support a means for setting a starting voltage of each read operation as a respective reference voltage for a voltage range. In some examples, the read component 430 may be configured as or otherwise support a means for setting an ending voltage of each read operation as a voltage associated with the threshold value in response to setting the starting voltage of each read operation, where determining whether the plurality of reference voltages satisfy the threshold value associated with the respective voltage range is in response to setting the ending voltage of each read operation.

In some examples, the determination component 435 may be configured as or otherwise support a means for determining a type of the memory cells from a plurality of types of memory cells, where each type of memory cell is associated with a respective quantity of voltage ranges, where setting the plurality of reference voltages for the plurality of voltage ranges is in accordance with determining the type of the memory cells.

In some examples, the plurality of types of memory cells include single-level cells (SLCs), multiple-level cells (MLCs), triple-level cells (TLCs), or quad-level cells (QLCs).

In some examples, to support reading the memory cells to identify the count of logic states, the read component 430 may be configured as or otherwise support a means for enabling a CTE read operation. In some examples, to support reading the memory cells to identify the count of logic states, the read component 430 may be configured as or otherwise support a means for setting a granularity for reading the memory cells.

In some examples, the determination component 435 may be configured as or otherwise support a means for determining whether the count of logic states within each respective voltage range satisfies a second threshold value, where storing the distribution of the voltage thresholds of the memory cells is in response to determining that the count of logic states within each respective voltage range satisfies the second threshold value.

In some examples, the second threshold value is based at least in part on a previous count of the logic states within each respective voltage range.

In some examples, an initial value for each reference voltage of the plurality of reference voltage includes a median voltage within a respective voltage range of the plurality of voltage ranges.

In some examples, the storing component 440 may be configured as or otherwise support a means for storing the count of logic states within each respective voltage to a memory array of the memory system.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

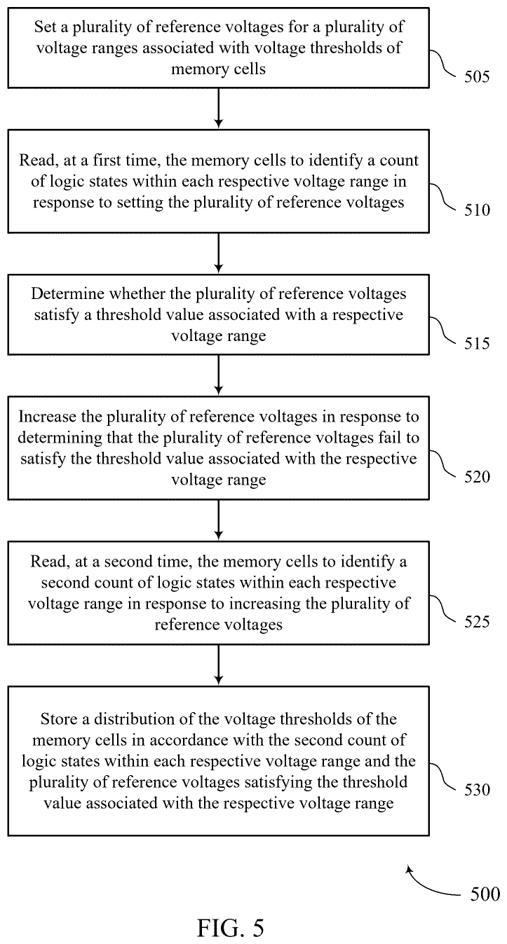

FIG. 5 shows a flowchart illustrating a method 500 that supports voltage threshold distribution using read estimate in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include setting a plurality of reference voltages for a plurality of voltage ranges associated with voltage thresholds of memory cells. In some examples, aspects of the operations of 505 may be performed by a reference component 425 as described with reference to FIG. 4.

At 510, the method may include reading, at a first time, the memory cells to identify a count of logic states within each respective voltage range in response to setting the plurality of reference voltages. In some examples, aspects of the operations of 510 may be performed by a read component 430 as described with reference to FIG. 4.

At 515, the method may include determining whether the plurality of reference voltages satisfy a threshold value associated with a respective voltage range. In some examples, aspects of the operations of 515 may be performed by a determination component 435 as described with reference to FIG. 4.

At 520, the method may include increasing the plurality of reference voltages in response to determining that the plurality of reference voltages fail to satisfy the threshold value associated with the respective voltage range. In some examples, aspects of the operations of 520 may be performed by a reference component 425 as described with reference to FIG. 4.

At 525, the method may include reading, at a second time, the memory cells to identify a second count of logic states within each respective voltage range in response to increasing the plurality of reference voltages. In some examples, aspects of the operations of 525 may be performed by a read component 430 as described with reference to FIG. 4.

At 530, the method may include storing a distribution of the voltage thresholds of the memory cells in accordance with the second count of logic states within each respective voltage range and the plurality of reference voltages satisfying the threshold value associated with the respective voltage range. In some examples, aspects of the operations of 530 may be performed by a storing component 440 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for setting a plurality of reference voltages for a plurality of voltage ranges associated with voltage thresholds of memory cells; reading, at a first time, the memory cells to identify a count of logic states within each respective voltage range in response to setting the plurality of reference voltages; determining whether the plurality of reference voltages satisfy a threshold value associated with a respective voltage range; increasing the plurality of reference voltages in response to determining that the plurality of reference voltages fail to satisfy the threshold value associated with the respective voltage range; reading, at a second time, the memory cells to identify a second count of logic states within each respective voltage range in response to increasing the plurality of reference voltages; and storing a distribution of the voltage thresholds of the memory cells in accordance with the second count of logic states within each respective voltage range and the plurality of reference voltages satisfying the threshold value associated with the respective voltage range.

Aspect 2: The method, apparatus, or non-transitory computer-readable medium of aspect 1, further including operations, features, circuitry, logic, means, or instructions, or any combination thereof for determining that the plurality of increased reference voltages satisfy the threshold value associated with the respective voltage range, where storing the distribution of the voltage thresholds of the memory cells is in response to determining that the plurality of increased reference voltages satisfy the threshold value associated with the respective voltage range.

Aspect 3: The method, apparatus, or non-transitory computer-readable medium of any of aspects 1 through 2, where increasing the plurality of reference voltages includes operations, features, circuitry, logic, means, or instructions, or any combination thereof for increasing a voltage of each reference voltage within the respective voltage range.

Aspect 4: The method, apparatus, or non-transitory computer-readable medium of any of aspects 1 through 3, further including operations, features, circuitry, logic, means, or instructions, or any combination thereof for setting a starting voltage of each read operation as a respective reference voltage for a voltage range and setting an ending voltage of each read operation as a voltage associated with the threshold value in response to setting the starting voltage of each read operation, where determining whether the plurality of reference voltages satisfy the threshold value associated with the respective voltage range is in response to setting the ending voltage of each read operation.

Aspect 5: The method, apparatus, or non-transitory computer-readable medium of any of aspects 1 through 4, further including operations, features, circuitry, logic, means, or instructions, or any combination thereof for determining a type of the memory cells from a plurality of types of memory cells, where each type of memory cell is associated with a respective quantity of voltage ranges, where setting the plurality of reference voltages for the plurality of voltage ranges is in accordance with determining the type of the memory cells.

Aspect 6: The method, apparatus, or non-transitory computer-readable medium of aspect 5, where the plurality of types of memory cells include single-level cells (SLCs), multiple-level cells (MLCs), triple-level cells (TLCs), or quad-level cells (QLCs).

Aspect 7: The method, apparatus, or non-transitory computer-readable medium of any of aspects 1 through 6, where reading the memory cells to identify the count of logic states includes operations, features, circuitry, logic, means, or instructions, or any combination thereof for enabling a CTE read operation and setting a granularity for reading the memory cells.

Aspect 8: The method, apparatus, or non-transitory computer-readable medium of any of aspects 1 through 7, further including operations, features, circuitry, logic, means, or instructions, or any combination thereof for determining whether the count of logic states within each respective voltage range satisfies a second threshold value, where storing the distribution of the voltage thresholds of the memory cells is in accordance with determining that the count of logic states within each respective voltage range satisfies the second threshold value.

Aspect 9: The method, apparatus, or non-transitory computer-readable medium of aspect 8, where the second threshold value is in accordance with a previous count of the logic states within each respective voltage range.

Aspect 10: The method, apparatus, or non-transitory computer-readable medium of any of aspects 1 through 9, where an initial value for each reference voltage of the plurality of reference voltage includes a median voltage within a respective voltage range of the plurality of voltage ranges.

Aspect 11: The method, apparatus, or non-transitory computer-readable medium of any of aspects 1 through 10, further including operations, features, circuitry, logic, means, or instructions, or any combination thereof for storing the count of logic states within each respective voltage to a memory array of the memory system.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
set a plurality of reference voltages for a plurality of voltage ranges associated with voltage thresholds of memory cells;
read, at a first time, the memory cells to identify a count of logic states within each respective voltage range in response to setting the plurality of reference voltages;
determine whether the plurality of reference voltages satisfy a threshold value associated with a respective voltage range;
increase the plurality of reference voltages in response to determining that the plurality of reference voltages fail to satisfy the threshold value associated with the respective voltage range;
read, at a second time, the memory cells to identify a second count of logic states within each respective voltage range in response to increasing the plurality of reference voltages; and
store a distribution of the voltage thresholds of the memory cells in accordance with the second count of logic states within each respective voltage range and the plurality of reference voltages satisfying the threshold value associated with the respective voltage range.

2. The memory system of claim 1, wherein the processing circuitry is further configured to cause the memory system to:
determine that the plurality of increased reference voltages satisfy the threshold value associated with the respective voltage range, wherein storing the distribution of the voltage thresholds of the memory cells is in response to determining that the plurality of increased reference voltages satisfy the threshold value associated with the respective voltage range.

3. The memory system of claim 1, wherein increasing the plurality of reference voltages comprises the processing circuitry configured to cause the memory system to:
increase a voltage of each reference voltage within the respective voltage range.

4. The memory system of claim 1, wherein the processing circuitry is further configured to cause the memory system to:
set a starting voltage of each read operation as a respective reference voltage for a voltage range; and
set an ending voltage of each read operation as a voltage associated with the threshold value in response to setting the starting voltage of each read operation, wherein determining whether the plurality of reference voltages satisfy the threshold value associated with the respective voltage range is in response to setting the ending voltage of each read operation.

5. The memory system of claim 1, wherein the processing circuitry is further configured to cause the memory system to:
determine a type of the memory cells from a plurality of types of memory cells, wherein each type of memory cell is associated with a respective quantity of voltage ranges, wherein setting the plurality of reference voltages for the plurality of voltage ranges is in accordance with determining the type of the memory cells.

6. The memory system of claim 5, wherein:
the plurality of types of memory cells include single-level cells (SLCs), multiple-level cells (MLCs), triple-level cells (TLCs), or quad-level cells (QLCs).

7. The memory system of claim 1, wherein reading the memory cells to identify the count of logic states comprises the processing circuitry configured to cause the memory system to:
enable a coarse threshold estimate (CTE) read operation; and
set a granularity for reading the memory cells.

8. The memory system of claim 1, wherein the processing circuitry is further configured to cause the memory system to:
determine whether the count of logic states within each respective voltage range satisfies a second threshold value, wherein storing the distribution of the voltage thresholds of the memory cells is in response to determining that the count of logic states within each respective voltage range satisfies the second threshold value.

9. The memory system of claim 8, wherein the second threshold value is in accordance with a previous count of the logic states within each respective voltage range.

10. The memory system of claim 1, wherein an initial value for each reference voltage of the plurality of reference voltages comprises a median voltage within a respective voltage range of the plurality of voltage ranges.

11. The memory system of claim 1, wherein the processing circuitry is further configured to cause the memory system to:
store the count of logic states within each respective voltage to a memory array of the memory system.

12. A non-transitory computer-readable medium storing code, the code comprising instructions executable by one or more processors to:
set a plurality of reference voltages for a plurality of voltage ranges associated with voltage thresholds of memory cells;
read, at a first time, the memory cells to identify a count of logic states within each respective voltage range in response to setting the plurality of reference voltages;
determine whether the plurality of reference voltages satisfy a threshold value associated with a respective voltage range;
increase the plurality of reference voltages in response to determining that the plurality of reference voltages fail to satisfy the threshold value associated with the respective voltage range;
read, at a second time, the memory cells to identify a second count of logic states within each respective voltage range in response to increasing the plurality of reference voltages; and
store a distribution of the voltage thresholds of the memory cells in accordance with the second count of logic states within each respective voltage range and the plurality of reference voltages satisfying the threshold value associated with the respective voltage range.

13. The non-transitory computer-readable medium of claim 12, wherein the instructions are further executable by the one or more processors to:
determine that the plurality of increased reference voltages satisfy the threshold value associated with the respective voltage range, wherein storing the distribution of the voltage thresholds of the memory cells in response to determining that the plurality of increased reference voltages satisfy the threshold value associated with the respective voltage range.

14. The non-transitory computer-readable medium of claim 12, wherein the instructions to increase the plurality of reference voltages are executable by the one or more processors to:
increase a voltage of each reference voltage within the respective voltage range.

15. The non-transitory computer-readable medium of claim 12, wherein the instructions are further executable by the one or more processors to:
set a starting voltage of each read operation as a respective reference voltage for a voltage range; and
set an ending voltage of each read operation as a voltage associated with the threshold value in response to setting the starting voltage of each read operation, wherein determining whether the plurality of reference voltages satisfy the threshold value associated with the respective voltage range is in response to setting the ending voltage of each read operation.

16. The non-transitory computer-readable medium of claim 12, wherein the instructions are further executable by the one or more processors to:
determine a type of the memory cells from a plurality of types of memory cells, wherein each type of memory cell is associated with a respective quantity of voltage ranges, wherein setting the plurality of reference voltages for the plurality of voltage ranges is in accordance with determining the type of the memory cells.

17. The non-transitory computer-readable medium of claim 12, wherein the instructions to read the memory cells to identify the count of logic states are executable by the one or more processors to:
enable a coarse threshold estimate (CTE) read operation; and
set a granularity for reading the memory cells.

18. The non-transitory computer-readable medium of claim 12, wherein the instructions are further executable by the one or more processors to:
determine whether the count of logic states within each respective voltage range satisfies a second threshold value, wherein storing the distribution of the voltage thresholds of the memory cells is in response to determining that the count of logic states within each respective voltage range satisfies the second threshold value.

19. A method by a memory system, comprising:
setting a plurality of reference voltages for a plurality of voltage ranges associated with voltage thresholds of memory cells;
reading, at a first time, the memory cells to identify a count of logic states within each respective voltage range in response to setting the plurality of reference voltages;
determining whether the plurality of reference voltages satisfy a threshold value associated with a respective voltage range;
increasing the plurality of reference voltages in response to determining that the plurality of reference voltages fail to satisfy the threshold value associated with the respective voltage range;
reading, at a second time, the memory cells to identify a second count of logic states within each respective voltage range in response to increasing the plurality of reference voltages; and
storing a distribution of the voltage thresholds of the memory cells in accordance with the second count of logic states within each respective voltage range and the plurality of reference voltages satisfying the threshold value associated with the respective voltage range.

20. The method of claim 19, further comprising:
determining that the plurality of increased reference voltages satisfy the threshold value associated with the respective voltage range, wherein storing the distribution of the voltage thresholds of the memory cells is in response to determining that the plurality of increased reference voltages satisfy the threshold value associated with the respective voltage range.

21. The method of claim 19, wherein increasing the plurality of reference voltages comprises:
increasing a voltage of each reference voltage within the respective voltage range.

22. The method of claim 19, further comprising:
setting a starting voltage of each read operation as a respective reference voltage for a voltage range; and
setting an ending voltage of each read operation as a voltage associated with the threshold value in response to setting the starting voltage of each read operation, wherein determining whether the plurality of reference voltages satisfy the threshold value associated with the respective voltage range is in response to setting the ending voltage of each read operation.

23. The method of claim 19, further comprising:
determining a type of the memory cells from a plurality of types of memory cells, wherein each type of memory cell is associated with a respective quantity of voltage ranges, wherein setting the plurality of reference voltages for the plurality of voltage ranges is in accordance with determining the type of the memory cells.

24. The method of claim 19, wherein reading the memory cells to identify the count of logic states comprises:
enabling a coarse threshold estimate (CTE) read operation; and
setting a granularity for reading the memory cells.

25. The method of claim 19, further comprising:
determining whether the count of logic states within each respective voltage range satisfies a second threshold value, wherein storing the distribution of the voltage thresholds of the memory cells is in response to determining that the count of logic states within each respective voltage range satisfies the second threshold value.
